(19) United States
(12) Patent Application Publication
(10) Pub. No.: US 2025/0188597 A1
(43) Pub. Date: Jun. 12, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Atsushi MORIYA, Toyama-shi (JP); Hideki HORITA, Toyama-shi (JP); Masahiro TAKAHASHI, Toyama-shi (JP)

(73) Assignee: KOKUSAI ELECTRIC CORPORATION, Tokyo (JP)

(21) Appl. No.: 19/060,256

(22) Filed: Feb. 21, 2025

Related U.S. Application Data
(63) Continuation of application No. PCT/JP2022/035548, filed on Sep. 23, 2022.

(51) Int. Cl. C23C 16/02; C23C 16/04; C23C 16/455; C23C 16/458; H01L 21/02

(52) U.S. Cl. CPC C23C 16/02; C23C 16/045; C23C 16/45561; C23C 16/4584; H01L 21/02532; H01L 21/02658

(57) ABSTRACT

The present disclosure provides a technique for improving step coverage in film formation. According to one embodiment, there is provided a technique including: (a1) modifying at least a portion of the substrate by supplying a first modifying gas to the substrate; (a2) adsorbing a first element preferentially to a region that is not modified by the first modifying gas, by supplying a first process gas containing the first element to the substrate; (b1) modifying at least a portion of the substrate by supplying a second modifying gas to the substrate, wherein a decomposition temperature of the second modifying gas is different from a decomposition temperature of the first modifying gas; and (b2) adsorbing a second element preferentially to a region that is not modified by the second modifying gas, by supplying a second process gas containing the second element to the substrate.

### CROSS-REFERENCE TO RELATED APPLICATION

This application is a Bypass Continuation Application of PCT International Application No. PCT/JP2022/035548, filed on Sep. 23, 2022, the entire contents of which are incorporated herein by reference.

### TECHNICAL FIELD

The present disclosure relates to a technique that is effective when applied to a method of processing a substrate, a method of manufacturing a semiconductor device, a substrate processing apparatus, and a recording medium.

### BACKGROUND

As device shapes have become finer and more complex in recent LSI manufacturing processes, there is a demand for a finer processing technique.

### SUMMARY

Some embodiments of the present disclosure provides a technique for improving step coverage and filling characteristics in film formation.

According to some embodiment of the present disclosure, there is provided a technique including (a1) modifying at least a portion of a substrate by supplying a first modifying gas to the substrate; (a2) adsorbing a first element preferentially to a region that is not modified by the first modifying gas, by supplying a first process gas containing the first element to the substrate; (b1) modifying at least a portion of the substrate by supplying a second modifying gas to the substrate, wherein a decomposition temperature of the second modifying gas is different from a decomposition temperature of the first modifying gas; and (b2) adsorbing a second element preferentially to a region that is not modified by the second modifying gas, by supplying a second process gas containing the second element to the substrate.

### BRIEF DESCRIPTION OF DRAWINGS

The accompanying drawings, which are incorporated in and constitute a part of the specification, illustrate embodiments of the present disclosure.

FIG. 1 is a longitudinal sectional view of a substrate processing apparatus according to an embodiment.

FIG. 2 is a block diagram showing the configuration of a controller included in the substrate processing apparatus of FIG. 1.

FIG. 3 is a diagram showing a first substrate processing method according to an embodiment.

FIG. 4 is a diagram showing a second substrate processing method according to an embodiment.

FIG. 5 is a view showing the configuration of a gas supply pipe system used in the second substrate processing method.

FIGS. 6A-6C are views for explaining film formation when a first modifying gas is used.

FIG. 7A is a view showing the adsorption location of the first modifying gas.

FIG. 7B is a view showing the adsorption location of a second modifying gas.

FIG. 8A is a view showing the adsorption location of the first modifying gas in a first film-forming step.

FIG. 8B is a view showing a film formed in the first film-forming step.

FIG. 8C is a view showing the adsorption location of the second modifying gas in a second film-forming step.

FIG. 8D is a view showing a film formed in the second film-forming step.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to unnecessarily obscure aspects of the various embodiments.

Embodiments will now be described in detail with reference to the drawings. However, in the following description, the same constituent elements are denoted by the same reference numerals and repeated description thereof may not be repeated. Note that the drawings may be shown in a schematic manner compared to the actual aspects in order to make the description clearer, but they are merely examples and do not limit the interpretation of the present disclosure. In addition, the drawings used in the following description are all schematic, and the dimensional relationship, ratios, and the like of various elements shown in the drawings may not always match the actual ones. Further, the dimensional relationship, ratios, and the like of various elements between plural figures may not always match each other.

### (1) Configuration of Substrate Processing Apparatus

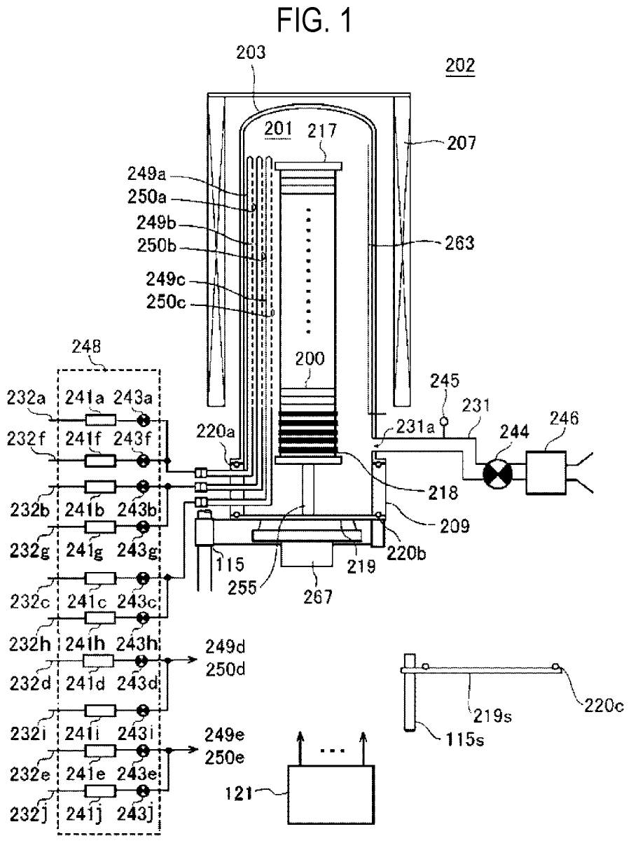

FIG. 1 is a schematic configuration view of a vertical process furnace of a substrate processing apparatus according to the present disclosure, in which a portion of the process furnace is shown in a vertical cross section. As shown in FIG. 1, a process furnace 202 includes a heater 207 as a heating mechanism (temperature adjustment part). The heater 207 has a cylindrical shape and is supported by a support plate so as to be vertically installed. The heater 207 also functions as an activation mechanism (an excitation part) that thermally activates (excites) a gas.

A reaction tube 203 is disposed inside the heater 207 to be concentric with the heater 207. The reaction tube 203 is made of, for example, a heat resistant material such as quartz (SiO₂) or silicon carbide (SiC), and has a cylindrical shape with its upper end closed and its lower end opened. A manifold 209 is disposed under the reaction tube 203 to be concentric with the reaction tube 203. The manifold 209 is made of, for example, a metal material such as stainless steel (SUS), and has a cylindrical shape with both of its upper and lower ends opened. The upper end portion of the manifold 209 engages with the lower end portion of the reaction tube 203 so as to support the reaction tube 203. An O-ring 220a serving as a seal member is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical portion of the process container. The process chamber 201 is configured to accommodate a plurality of wafers 200 as substrates. Processing on the wafers 200 is performed in the process chamber 201.

Nozzles 249a to 249e as first to fifth supply parts are provided in the process chamber 201 so as to penetrate through a sidewall of the manifold 209. Three nozzles, nozzles 249a to 249c, are depicted in FIG. 1, and two nozzles, nozzles 249d to 249e, are omitted from the figure because they would make the figure complicated. The nozzles 249a to 249e are also referred to as first to fifth nozzles, respectively. The nozzles 249a to 249e are made of, for example, a heat resistant material such as quartz or SiC. Gas supply pipes 232a to 232e are connected to the nozzles 249a to 249e, respectively. The nozzles 249a to 249e are different nozzles.

Mass flow controllers (MFCs) 241a to 241e, which are flow rate controllers (flow rate control parts), and valves 243a to 243e, which are opening/closing valves, are provided in the gas supply pipes 232a to 232e, respectively, sequentially from the upstream side of a gas flow. Gas supply pipes 232f to 232j is connected to the gas supply pipes 232a to 232e at the downstream side of the valves 243a to 243e, respectively. MFCs 241f to 241j and valves 243f to 243j are provided in the gas supply pipes 232f to 232j, respectively, sequentially from the upstream side of a gas flow. The gas supply pipes 232a to 232j are made of, for example, a metal material such as SUS.

The nozzles 249a to 249e are provided in an annular space in plan view between an inner wall of the reaction tube 203 and the wafers 200 so as to extend upward from a lower portion of the inner wall of the reaction tube 203 to an upper portion thereof, that is, along an arrangement direction of the wafers 200. Specifically, the nozzles 249a to 249e are provided in a region horizontally surrounding a wafer arrangement region in which the wafers 200 are arranged at a lateral side of the wafer arrangement region, along the wafer arrangement region. For example, in plan view, the nozzle 249c is disposed so as to face an exhaust port 231a to be described later on a straight line with the centers of the wafers 200 loaded into the process chamber 201, which are interposed therebetween. The nozzles 249a and 249b and the nozzles 249d and 249e are arranged so as to sandwich a straight line passing through the nozzle 249c and the center of the exhaust port 231a from both sides along the inner wall of the reaction tube 203 (the outer peripheral portion of the wafers 200). The straight line is also a straight line passing through the nozzle 249c and the centers of the wafers 200. That is, it can be said that the nozzle 249c is provided on the side opposite to the nozzle 249a with the straight line L interposed therebetween. The nozzles 249a, 249b and the nozzles 249d and 249e are arranged in line symmetry with the straight line as the axis of symmetry. Gas supply holes 250a to 250d for supplying a gas are formed on the side surfaces of the nozzles 249a to 249e, respectively. Each of the gas supply holes 250a to 250d is opened so as to oppose (face) the exhaust port 231a in plan view, which enables a gas to be supplied toward the wafers 200. A plurality of gas supply holes 250a to 250d are formed from the lower portion of the reaction tube 203 to the upper portion thereof.

From the gas supply pipe 232a, a first process gas (first precursor gas) containing a first element, for example, a Si-containing gas containing silicon (Si) as the first element, can be used. As the Si-containing gas, for example, a silane gas containing Si as the main element is supplied into the process chamber 201 via the MFC 241a, the valve 243a, and the nozzle 249a.

From the gas supply pipe 232b, a first modifying gas (first film formation inhibiting gas, first inhibitor), for example, a gas containing Si as the first element and a halogen element, i.e., a halosilane gas, is supplied into the process chamber 201 via the MFC 241b, the valve 243b, and the nozzle 249b.

From the gas supply pipe 232c, a second process gas (second precursor gas) containing a second element, for example, a silane gas containing Si as the second element, is supplied into the process chamber 201 via the MFC 241c, the valve 243c, and the nozzle 249c.

From the gas supply pipe 232d, a second modifying gas (second film formation inhibiting gas, second inhibitor), for example, a gas containing Si as the second element and a halogen element, i.e., a halosilane gas, is supplied into the process chamber 201 via the MFC 241d, the valve 243d, and the nozzle 249d.

From the gas supply pipe 232e, a reaction gas is supplied into the process chamber 201 via the MFC 241e, the valve 243e, and the nozzle 249e.

From the gas supply pipes 232f to 232j, an inert gas, for example, a nitrogen (N₂) gas, is supplied into the process chamber 201 via the MFCs 241f to 241j, the valves 243f to 243j, and the nozzles 249a to 249e. The inert gas acts as a purge gas, a carrier gas, a dilution gas, etc.

A first process gas (first precursor gas) supply system mainly includes the gas supply pipe 232a, the MFC 241a, and the valve 243a. A first modifying gas supply system mainly includes the gas supply pipe 232b, the MFC 241b, and the valve 243b. A second process gas (second precursor gas) supply system mainly includes the gas supply pipe 232c, the MFC 241c, and the valve 243c. A second modifying gas supply system mainly includes the gas supply pipe 232d, the MFC 241d, and the valve 243d. A reaction gas supply system mainly includes the gas supply pipe 232e, the MFC 241e, and the valve 243e. An inert gas supply system mainly includes the gas supply pipes 232f to 232j, the MFCs 241f to 241j, and the valves 243f to 243j.

One or all of the above-described various supply systems may be configured as an integrated-type supply system 248 in which the valves 243a to 243j, the MFCs 241a to 241j, and so on are integrated. The integrated-type supply system 248 is connected to each of the gas supply pipes 232a to 232j. In addition, the integrated-type supply system 248 is configured such that operations of supplying various kinds of gases into the gas supply pipes 232a to 232j, that is, the opening/closing operation of the valves 243a to 243j, the flow rate adjustment operation by the MFCs 241a to 241j, and the like, are controlled by a controller 121 which will be described later. The integrated-type supply system 248 is configured as an integral type or detachable-type integrated unit, and may be attached to and detached from the gas supply pipes 232a to 232j and the like on an integrated unit basis, so that the maintenance, replacement, extension, etc. of the integrated-type supply system 248 can be performed on an integrated unit basis.

The exhaust port 231a for exhausting an internal atmosphere of the process chamber 201 is provided below the sidewall of the reaction tube 203. The exhaust port 231a is provided at a position opposing (facing) the nozzles 249a to 249e (the gas supply holes 250a to 250e) with the wafers 200 interposed therebetween. The exhaust port 231a may be provided along the sidewall of the reaction tube 203 from a lower portion of the sidewall of the reaction tube 203 to an upper portion thereof, that is, along the wafer arrangement region. An exhaust pipe 231 is connected to the exhaust port 231a. A vacuum pump 246 as a vacuum exhaust device is connected to the exhaust pipe 231 via a pressure sensor 245, which is a pressure detector (pressure detection part) for detecting the internal pressure of the process chamber 201, and an auto pressure controller (APC) valve 244, which is a pressure regulator (pressure adjustment part). The APC valve 244 is configured to perform or stop a vacuum exhausting operation in the process chamber 201 by opening/closing the valve while the vacuum pump 246 is actuated, and is also configured to adjust the internal pressure of the process chamber 201 by adjusting an opening degree of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219 as a furnace opening cover, which can hermetically seal a lower end opening of the manifold 209, is provided under the manifold 209. The seal cap 219 is made of, for example, a metal material such as SUS, and is formed in a disc shape. An O-ring 220b, which is a seal member making contact with the lower end of the manifold 209, is provided on an upper surface of the seal cap 219. A rotation mechanism 267, which rotates a boat 217, which will be described later, is installed under the seal cap 219. A rotary shaft 255 of the rotation mechanism 267 is connected to the boat 217 through the seal cap 219. The rotation mechanism 267 is configured to rotate the wafers 200 by rotating the boat 217. The seal cap 219 is configured to be vertically moved up and down by a boat elevator 115 which is an elevating mechanism installed outside the reaction tube 203. The boat elevator 115 is configured as a transfer device (transfer mechanism) which loads/unloads (transfers) the wafers 200 into/out of the process chamber 201 by moving the seal cap 219 up and down. A shutter 219s as a furnace opening cover, which can hermetically seal a lower end opening of the manifold 209 in a state where the seal cap 219 is lowered and the boat 217 is unloaded from the process chamber 201, is provided under the manifold 209. The shutter 219s is made of, for example, a metal material such as SUS, and is formed in a disc shape. An O-ring 220c, which is a seal member making contact with the lower end of the manifold 209, is provided on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 sheets of wafer, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of a heat-resistant material such as quartz or SiC are installed below the boat 217 in multiple stages.

Note that in the present disclosure, a numerical range such as “25 to 200 sheets” means that the lower limit and the upper limit are included in the range. Thus, for example, “25 to 200 sheets” means “25 sheets or more and 200 sheets or less”. The same applies to other numerical ranges.

A temperature sensor 263 serving as a temperature detector is installed in the reaction tube 203. Based on temperature information detected by the temperature sensor 263, a state of supplying electric power to the heater 207 is adjusted such that an interior of the process chamber 201 has a desired temperature distribution. The temperature sensor 263 is provided along the inner wall of the reaction tube 203.

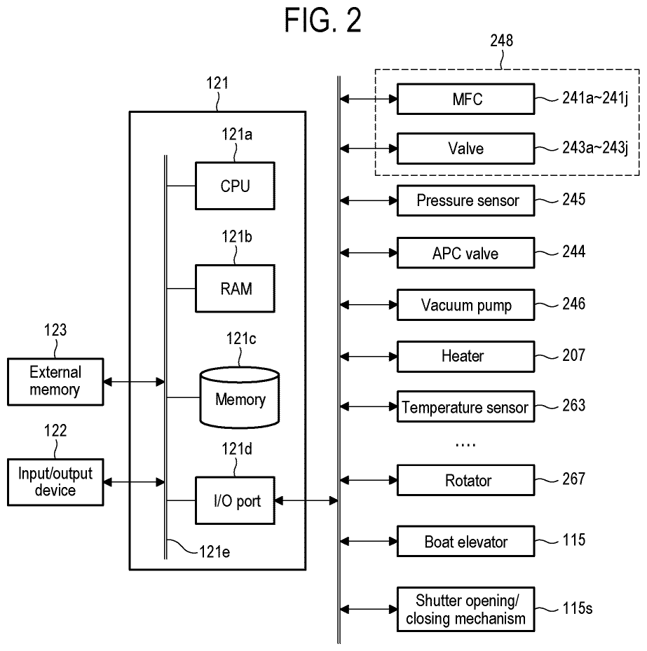

As shown in FIG. 2, a controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, e.g., a touch panel or the like, is connected to the controller 121.

The memory 121c is configured by, for example, a flash memory, a hard disk drive (HDD), or the like. A control program for controlling operations of a substrate processing apparatus, a process recipe in which sequences and conditions of substrate processing to be described later are written, etc. are readably stored in the memory 121c. The process recipe functions as a program that causes the controller 121 to execute each sequence in the substrate processing, which will be described later, to obtain an expected result. Hereinafter, the process recipe and the control program may be generally and simply referred to as a “program”. Furthermore, the process recipe may be simply referred to as a “recipe”. When the term “program” is used herein, it may indicate a case of including the recipe only, a case of including the control program only, or a case of including both the recipe and the control program. The RAM 121b is configured as a memory area (work area) in which programs or data read by the CPU 121a are temporarily stored.

The I/O port 121d is connected to the MFCs 241a to 241j, the valves 243a to 243j, the pressure sensor 245, the APC valve 244, the vacuum pump 246, the temperature sensor 263, the heater 207, the rotation mechanism 267, the boat elevator 115, the shutter opening/closing mechanism 115s, and so on.

The CPU 121a is configured to be able to read and execute the control program from the memory 121c. The CPU 121a is also configured to be able to read the recipe from the memory 121c according to an input of an operation command from the input/output device 122. The CPU 121a is configured to be able to control the flow rate adjusting operation of various kinds of gases by the MFCs 241a to 241j, the opening/closing operation of the valves 243a to 243j, the opening/closing operation of the APC valve 244, the pressure adjusting operation performed by the APC valve 244 based on the pressure sensor 245, the actuating and stopping operation of the vacuum pump 246, the temperature adjusting operation performed by the heater 207 based on the temperature sensor 263, the operation of rotating the boat 217 with the rotation mechanism 267 and adjusting the rotation speed of the boat 217, the operation of moving the boat 217 up and down by the boat elevator 115, the opening/closing operation of the shutter 219s by the shutter opening/closing mechanism 115s, and so on, according to contents of the read recipe.

The controller 121 can be configured by installing, on the computer, the aforementioned program stored in an external memory 123. Examples of the external memory 123 may include a magnetic disk such as a HDD, an optical disc such as a CD, a magneto-optical disc such as a MO, a semiconductor memory such as a USB memory, and the like. The memory 121c or the external memory 123 is configured as a computer-readable recording medium. Hereinafter, the memory 121c and the external memory 123 may be generalized and simply referred to as a “recording medium”. When the term “recording medium” is used herein, it may indicate a case of including the memory 121c only, a case of including the external memory 123 only, or a case of including both the memory 121c and the external memory 123. Furthermore, the program may be provided to the computer using communication means such as the Internet or a dedicated line, instead of using the external memory 123.

### (2) Substrate Processing Process

### (2-1) First Substrate Processing Method

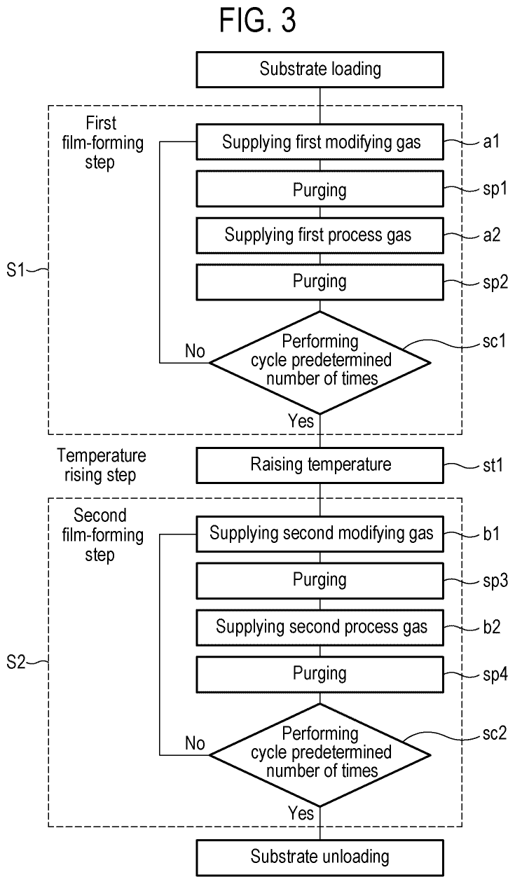

FIG. 3 is a diagram showing a first substrate processing method according to an embodiment. As one process of a method of manufacturing a semiconductor device, an example of a process of a substrate processing method of forming, for example, a film containing a first element (first film, first layer) and a film containing a second element (second film, second layer) on a wafer 200 will be described with reference to FIG. 3. In this example, the process is to form a film containing a first element and a film containing a second element inside a recess formed on the surface of the wafer 200, and is performed using the process furnace 202 of the above-described substrate processing apparatus 10. In the following description, the operation of each part constituting the substrate processing apparatus 10 is controlled by the controller 121.

A substrate processing process (semiconductor device manufacturing process) according to this embodiment includes: for example,
(a1) a step of modifying at least a portion of a substrate (wafer 200) by supplying a first modifying gas (first film formation inhibiting gas, first inhibitor) to the substrate;
(a2) a step of supplying a first process gas (first precursor gas) containing a first element to the substrate and preferentially adsorbing the first element to a region not modified by the first modifying gas;
(b1) a step of modifying at least a portion of the substrate by supplying, to the substrate, a second modifying gas (second film formation inhibiting gas, second inhibitor) having a decomposition temperature different from that of the first modifying gas; and
(b2) a step of supplying a second process gas (second precursor gas) containing a second element to the substrate and preferentially adsorbing the second element to a region not modified by the second modifying gas.

When the term “wafer” is used in the present disclosure, it may refer to “a wafer itself” or “a wafer and a stacked body of certain layers or films formed on a surface of the wafer”. When the phrase “a surface of a wafer” is used in the present disclosure, it may refer to “a surface of a wafer itself” or “a surface of a certain layer formed on a wafer”. When the expression “a certain layer is formed on a wafer” is used in the present disclosure, it may mean that “a certain layer is formed directly on a surface of a wafer itself” or that “a certain layer is formed on a layer formed on a wafer”. When the term “substrate” is used in the present disclosure, it may be synonymous with the term “wafer”.

In the present disclosure, a processing temperature means the temperature of the wafer 200 or the internal temperature of the process chamber 201, and a processing pressure means the internal pressure of the process chamber 201. In addition, a processing time means the time during which the processing continues. These terms are the same in the following description.

### (Substrate Loading Step)

In a substrate loading step, (wafer charging and boat loading) and (pressure adjustment and temperature adjustment) are performed.

### (Wafer Charging and Boat Loading)

When the boat 217 is charged with a plurality of wafers 200 (wafer charging), the shutter 219s is moved by the shutter opening/closing mechanism 115s and the lower end opening of the manifold 209 is opened (shutter open). Thereafter, as shown in FIG. 1, the boat 217 charged with the plurality of wafers 200 is lifted up by the boat elevator 115 to be loaded into the process chamber 201 (boat loading). In this state, the seal cap 219 seals the lower end of the manifold 209 through the O-ring 220b.

### (Pressure Adjustment and Temperature Adjustment)

The interior of the process chamber 201, that is, a space where the wafers 200 are placed, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the measured pressure information. Further, the wafers 200 in the process chamber 201 are heated by the heater 207 so as to have a desired temperature. At this time, the state of supplying electric power to the heater 207 is feedback-controlled based on the temperature information detected by the temperature sensor 263 so that the interior of the process chamber 201 has a desired temperature distribution. Further, the rotation of the wafers 200 by the rotation mechanism 267 is started. The exhaust of the interior of the process chamber 201 and the heating and rotation of the wafers 200 are continuously performed at least until the processing on the wafers 200 is completed.

### (First Film-Forming Step: S1)

Next, a first film-forming step S1 is performed. In the first film-forming step S1, the following steps (processes) are performed.

### (Step a1)

In this step, a first modifying gas is supplied to the wafer 200 in the process chamber 201 to modify at least a portion of the wafer 200.

Specifically, the valve 243b is opened to allow the first modifying gas to flow into the gas supply pipe 232b. The flow rate of the first modifying gas is adjusted by the MFC 241b, and the first modifying gas is supplied into the process chamber 201 via the nozzle 249b and is exhausted through the exhaust port 231a. In this operation, the first modifying gas is supplied to the wafer 200 (first modifying gas supplying step). At this time, the valves 243f, 243h, 243i, and 243j are opened to allow a N₂ gas to be supplied into the process chamber 201 via the nozzles 249a, 249c, 249d, and 249e, respectively.

(Purging Step sp1)

Thereafter, the valve 243b is closed to stop the supply of the first modifying gas into the process chamber 201. Then, the interior of the process chamber 201 is vacuum-exhausted to remove a gas and the like remaining in the process chamber 201 from the process chamber 201. At this time, the valves 243f to 243j are opened to allow a N₂ gas to be supplied into the process chamber 201 via the nozzles 249a to 249e, respectively. The N₂ gas supplied from the nozzles 249a to 249e acts as a purge gas, thereby purging the interior of the process chamber 201.

### (Step a2)

After step a1 is completed, a first process gas (first precursor gas) is supplied to the surface of the wafer 200 in the process chamber 201. The adsorption of the first process gas is inhibited at locations of the surface of the wafer 200 where the first modifying gas was adsorbed in step a1. That is, in step a2, the first process gas containing a first element is supplied to the wafer 200, and the first element is preferentially adsorbed onto a region of the wafer 200 that has not been modified by the first modifying gas.

Specifically, the valve 243a is opened to allow the first process gas to flow into the gas supply pipe 232a. The flow rate of the first process gas is adjusted by the MFC 241a, and the first process gas is supplied into the process chamber 201 via the nozzle 249a and is exhausted through the exhaust port 231a. In this operation, the first process gas is supplied to the wafer 200 (first process gas supplying step). At this time, the valves 243g to 243i are opened to allow a N₂ gas to be supplied into the process chamber 201 via the nozzles 249b to 249d respectively.

(Purging Step sp2)

After nuclei are formed on the surface of the wafer 200, the valve 243a is closed to stop the supply of the first process gas into the process chamber 201. Then, a gas and the like remaining in the process chamber 201 are removed from the process chamber 201 according to the same process procedures as in the purging step sp1.

[Predetermined Number of Times Performing Step sc1]

By performing a cycle a predetermined number of times (n1 times, where n1 is an integer of 1 or more), the cycle including alternately, i.e., non-simultaneously without synchronization, performing the above-described steps a1 and a2, a film containing the first element can be formed on the wafer 200.

In the first film-forming step, it is possible to control the thickness of the film containing the first element formed on the wafer 200 by controlling at least one of the processing temperature and processing time (first modifying gas and first process gas supply time) shown below. In addition, in the first film-forming step, it is also possible to control the thickness of the film containing the first element formed on the wafer 200 by controlling the number of times of performance of the above-mentioned cycle (the number of cycles).

The process conditions in step a1 are exemplified as follows:
First modifying gas supply flow rate: 10 to 1,000 sccm
First modifying gas supply time: 0.5 to 10 minutes
N₂ gas supply flow rate (for each gas supply pipe): 10 to 10,000 sccm
Processing temperature (first temperature): 350 to 420 degrees C.
Processing pressure: 100 to 1,000 Pa

The process conditions in step a2 are exemplified as follows:
First process gas supply flow rate: 10 to 1,000 sccm
First process gas supply time: 0.5 to 10 minutes

Other process conditions are the same as those in step a1.

### (Temperature Rising Step st1: Temperature Adjusting Step)

After the film containing the first element is formed on the wafer 200, the output of the heater 207 is adjusted so as to change the internal temperature of the process chamber 201, i.e., the temperature of the wafer 200, to a second temperature higher than the above-mentioned first temperature. When performing this step, the valves 243f to 243j are opened to allow a N₂ gas to be supplied into the process chamber 201 via the nozzles 249a to 249e, and the gas is exhausted through the exhaust port 231a to purge the interior of the process chamber 201. After the temperature of the wafer 200 reaches the second temperature and stabilizes, a second film-forming step to be described below is started.

### (Second Film-Forming Step: S2)

Next, a second film-forming step S2 is performed. In the second film-forming step S2, the following steps (processes) are performed.

### (Step b1)

In this step, a second modifying gas having a decomposition temperature different from that of the first modifying gas is supplied to the wafer 200 in the process chamber 201, i.e., the surface of the film containing the first element formed on the wafer 200, to modify at least a portion of the substrate. Here, an example is described in which the decomposition temperature of the first modifying gas is lower than that of the second modifying gas.

Specifically, the valve 243d is opened to allow the second modifying gas to flow into the gas supply pipe 232d. The flow rate of the second modifying gas is adjusted by the MFC 241d, and the second modifying gas is supplied into the process chamber 201 via the nozzle 249d and is exhausted through the exhaust port 231a. In this operation, the second modifying gas is supplied to the wafer 200 (second modifying gas supplying step). At this time, the valves 243f, 243g, 243h, and 243j are opened to allow a N₂ gas to be supplied into the process chamber 201 via the nozzles 249a, 249b, 249c, and 249e, respectively.

(Purging Step sp3)

Thereafter, the valve 243b is closed to stop the supply of the second modifying gas into the process chamber 201. Then, the interior of the process chamber 201 is vacuum-exhausted to remove a gas and the like remaining in the process chamber 201 from the process chamber 201. At this time, the valves 243f to 243j are opened to allow a N₂ gas to be supplied into the process chamber 201 via the nozzles 249a to 249e, respectively. The N₂ gas supplied from nozzles 249a to 249c acts as a purge gas, thereby purging the interior of the process chamber 201.

### (Step b2)

After step b1 is completed, a second process gas (second precursor gas) is supplied to the surface of the wafer 200 in the process chamber 201. The adsorption of the second process gas is inhibited at locations of the surface of the wafer 200 where the second modifying gas was adsorbed in step a1. That is, in this step, the second process gas containing a second element is supplied to the wafer 200, and the second element is preferentially adsorbed to a region of the wafer 200 that has not been modified by the second modifying gas.

Specifically, the valve 243c is opened to allow the second process gas to flow into the gas supply pipe 232c. The flow rate of the second process gas is adjusted by the MFC 241c, and the second process gas is supplied into the process chamber 201 via the nozzle 249c and is exhausted through the exhaust port 231a. In this operation, the second process gas is supplied to the wafer 200 (second process gas supplying step). At this time, the valves 243g to 243i are opened to allow a N₂ gas to be supplied into the process chamber 201 via the nozzles 249b to 249d, respectively.

(Purging Step sp4)

After the film containing the second element is formed on the surface of the wafer 200, the valve 243c is closed to stop the supply of the second process gas into the process chamber 201. Then, a gas and the like remaining in the process chamber 201 are removed from the process chamber 201 according to the same process procedures as in the purging step sp3.

[Predetermined Number of Times Performing Step sc2]

By performing a cycle a predetermined number of times (n2 times, where n2 is an integer of 1 or more), the cycle including alternately, i.e., non-simultaneously without synchronization, performing the above-described steps b1 and b2, a film containing the second element can be formed on the film containing the first element on the wafer 200.

The process conditions in the second film-forming step S2 are exemplified as follows:
Second modifying gas supply flow rate: 10 to 5,000 sccm
Second modifying gas supply time: 1 to 300 minutes
Second process gas supply flow rate: 10 to 5,000 sccm
Second process gas supply time: 1 to 300 minutes
N₂ gas supply flow rate (for each gas supply pipe): 10 to 20,000 sccm
Processing temperature (second temperature): 450 to 550 degrees C.
Processing pressure: 30 to 400 Pa

### (Substrate Unloading Step)

In a substrate unloading step, the following steps are performed.

### (After-Purging and Returning to Atmospheric Pressure)

After the formation of the film containing the second element on the wafer 200 is completed, a N₂ gas is supplied as a purge gas into the process chamber 201 from each of the nozzles 249a to 249e and is exhausted through the exhaust port 231a. Thus, the interior of the process chamber 201 is purged and a gas, reaction by-products, and the like remaining in the process chamber 201 are removed from the process chamber 201 (after-purging). After that, the internal atmosphere of the process chamber 201 is substituted with the inert gas (inert gas substitution) and the internal pressure of the process chamber 201 is returned to the atmospheric pressure (returning to atmospheric pressure).

### (Boat Unloading and Wafer Discharging)

The seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter close). After being unloaded to the outside of the reaction tube 203, the processed wafers 200 are taken out from the boat 217 (wafer discharging).

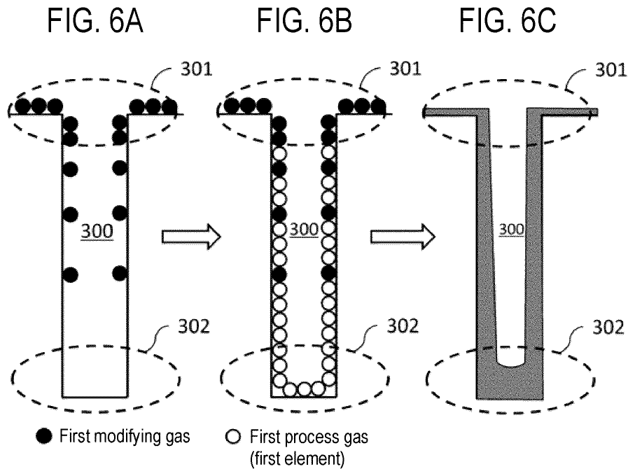

One method for obtaining a film with good step coverage will be described with reference to FIGS. 6A to 6C. FIG. 6 shows an example in which a trench (groove) 300, which is a recess, is formed on the surface of the substrate 200, and a first process gas (first element) is adsorbed inside the trench 300. When a first modifying gas is supplied to the substrate surface as shown in FIG. 6A, the number of times of collision with the gas is larger in the upper portion 301 of the trench (near the entrance of the recess) than in the lower portion 302 of the trench 300 (deep portion of the recess). This allows the first modifying gas to be preferentially adsorbed onto (or reacted with) the upper portion 301 of the trench. When the first process gas is supplied to the surface of the substrate 200 after the first modifying gas is supplied, since the first modifying gas is adsorbed onto the upper portion 301 of the trench, the adsorption of the first process gas (first element) is inhibited, and the first process gas is adsorbed onto the lower portion 302 of the trench (FIG. 6B). That is, in the first film-forming step, the first process gas containing the first element is supplied to the wafer 200, and the first element is preferentially adsorbed onto the lower portion 302 of the trench that has not been modified by the first modifying gas. As a result, the amount of the first element adsorbed onto the upper portion 301 of the trench is small, so that an increase in the thickness of the film formed is suppressed, while the amount of the first element adsorbed onto the lower portion 302 of the trench is sufficient, so that an increase in the film thickness can be promoted (FIG. 6C). Therefore, a film 303 containing the first element with better step coverage can be obtained.

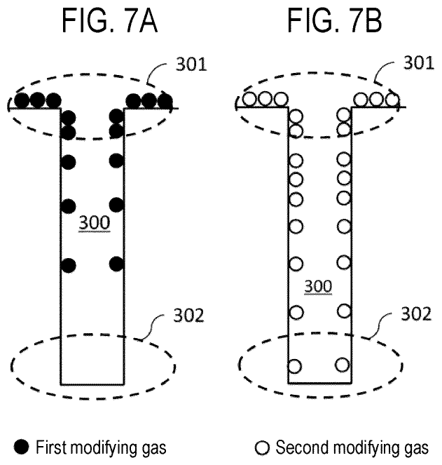

In the example shown in the first substrate processing method, the decomposition temperature of the first modifying gas is different from that of the second modifying gas, and the first modifying gas has a lower decomposition temperature than the second modifying gas. This can be said in other words that the first modifying gas is more easily decomposed or has a higher reactivity than the second modifying gas. In such a case, the adsorption locations of the first modifying gas in the trench 300 are shown in FIG. 7A, and the adsorption locations of the second modifying gas in the trench 300 are shown in FIG. 7B. In order for a gas to be adsorbed onto the lower portion 302 of the trench, it is necessary for the gas to penetrate into the trench 300 from the upper portion 301 of the trench and reach the lower portion 302 of the trench without being decomposed. On the other hand, since the gas can reach the upper portion 301 of the trench more easily than the lower portion 302 of the trench, the ease of adsorption of the gas due to the decomposition temperature in the upper portion 301 of the trench does not change as much as in the lower portion 302 of the trench.

Therefore, it can be said that the first modifying gas is less likely to modify the lower portion 302 of the trench than the second modifying gas, or that the first modifying gas preferentially adsorbs onto (or reacts with) the upper portion 301 of the trench. It can also be said that the second modifying gas modifies the trench lower portion 302 side rather than a region in the trench 300 modified by the first modifying gas. It can also be said that the second modifying gas can modify the trench lower portion 302 side rather than the region in the trench 300 modified by the first modifying gas.

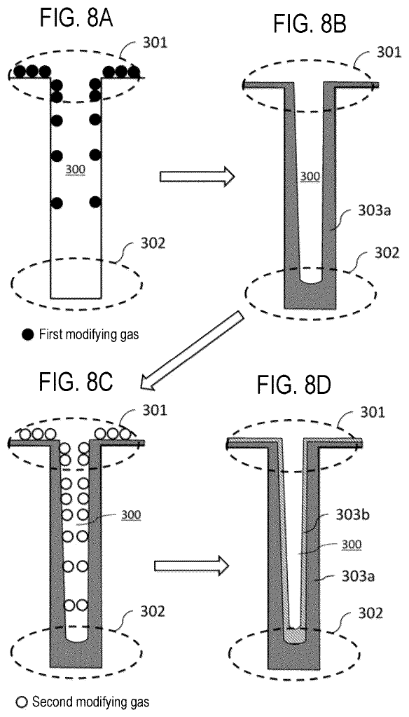

For example, when the first film-forming step and the second film-forming step are performed as described above, the first modifying gas preferentially modifies the upper portion 301 of the trench (FIG. 8A). As a result, the adsorption of the first element is inhibited in the upper portion 301 of the trench, and a film 303a containing the first element can be formed in the lower portion 302 of the trench so as not to inhibit the adsorption of the first element (FIG. 8B). After that, the second modifying gas modifies a wider region on the trench lower portion 302 side than the first modifying gas (FIG. 8C). As a result, a film 303b containing the second element can be formed with a more uniform film thickness than the film 303a over the entire trench 300 while suppressing an increase in the film thickness in the upper portion 301 of the trench (FIG. 8D). This allows a film to be formed uniformly with good step coverage over the entire trench 300.

In addition, by making the temperature different between the first film-forming step and the second film-forming step as described above, the ease of decomposition of the first modifying gas and the second modifying gas changes. This allows the regions in the trench 300 modified by the first and second modifying gases to be changed, respectively, and therefore allows the adsorption locations of the first and second elements to be controlled. In addition, by making the temperature different between the first film-forming step and second film-forming step, the ease of decomposition of the first process gas or the second process gas can be controlled. For example, by making the temperature in the second film-forming step higher than that in the first film-forming step, the second process gas is made more likely to be decomposed, so that the thickness of the film containing the second element formed in the upper portion 301 of the trench can be increased.

In addition, the first process gas (first precursor gas) may have a lower decomposition temperature than the second process gas (second precursor gas). In this case, since the first process gas is more easily decomposed than the second process gas, a film can be formed at a high rate even in the lower portion 302 of the trench which is difficult for the gas to reach. In addition, since the second process gas is less likely to be decomposed than the first process gas, a difference in the amount of decomposition between the upper portion 301 of the trench 301 and the lower portion 302 of the trench 302 is smaller, so that it is easier to form a film with a uniform thickness. Therefore, it is possible to form a film uniformly with good step coverage over the entire trench 300.

Note that the upper portion 301 of the trench can be rephrased as a location where the gas can easily reach, and the lower portion 302 of the trench 302 can be rephrased as a location where the gas cannot easily reach. In this case, since the first modifying gas is less likely to adsorb onto the location where the gas cannot easily reach, it mainly modifies the location where the gas can easily reach. Therefore, in step a2, the first process gas can adsorb the first element onto the location where the gas cannot easily reach, while inhibiting the adsorption of the first element to the location where the gas can easily reach. After that, by using the second modifying gas that is easily adsorbed even onto the location where the gas cannot easily reach, a film containing the second element can be formed with good step coverage in step b2.

In the first substrate processing method, an example has been described in which the film containing the second element is formed on the film containing the first element by performing the second film-forming step after the first film-forming step. The method disclosed herein is not limited thereto, and can also be suitably used, for example, in a case of forming a film in which the film containing the first element and the film containing the second element are laminated by performing a cycle a predetermined number of times, the cycle including the first film-forming step and the second film-forming step.

### (2-2) Second Substrate Processing Method

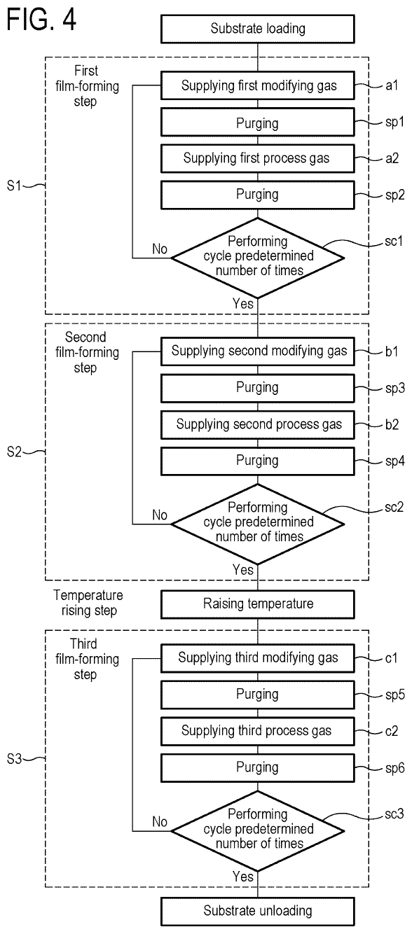

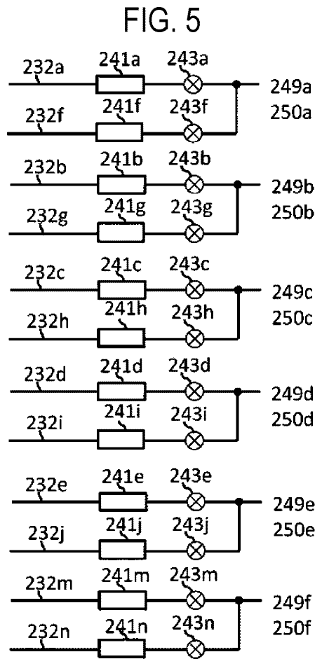

FIG. 4 is a diagram showing a second substrate processing method according to an embodiment. FIG. 5 is a view showing the configuration of a gas supply pipe system used in the second substrate processing method.

The second substrate processing method shown in FIG. 4 includes a first film-forming step, a second film-forming step, and a third film-forming step. The third film-forming step in FIG. 4 corresponds to the second film-forming step in FIG. 3. The first film-forming step in FIG. 3 can be considered to be divided into the first film-forming step and the second film-forming step in FIG. 4.

In FIG. 4, the first film-forming step and the second film-forming step are performed at the same first processing temperature, and the third film-forming step is performed at a second processing temperature higher than the first processing temperature.

In the gas supply pipe system, as shown in FIG. 5, a gas supply pipe 232m, an MFC 241m, a valve 243m, a gas supply pipe 232n, an MFC 241n, a valve 243n, a nozzle 249f, and a gas supply hole 250f are added as compared to the gas supply pipe system in FIG. 1.

The second substrate processing method will be described below with reference to FIG. 4, but the same parts as those in FIG. 3 will not be described.

### (First Film-Forming Step: S1)

In a first film-forming step S1, the following steps (processes) are performed.

### (Step a1)

In this step, a first modifying gas is supplied to the wafer 200 in the process chamber 201 to modify at least a portion of the wafer 200.

Specifically, the valve 243b is opened to allow the first modifying gas to flow into the gas supply pipe 232b. The flow rate of the first modifying gas is adjusted by the MFC 241b, and the first modifying gas is supplied into the process chamber 201 via the nozzle 249b and is exhausted through the exhaust port 231a. In this operation, the first modifying gas is supplied to the wafer 200 (first modifying gas supplying step). At this time, the valves 243f, 243h, 243i, 243j, and 243n are opened to allow a N₂ gas to be supplied into the process chamber 201 via the nozzles 249a, 249c, 249d, 249e, and 249f, respectively.

(Purging Step sp1)

Thereafter, the valve 243b is closed to stop the supply of the first modifying gas into the process chamber 201. Then, the interior of the process chamber 201 is vacuum-exhausted to remove a gas and the like remaining in the process chamber 201 from the process chamber 201. At this time, the valves 243f to 243n are opened to allow a N₂ gas to be supplied into the process chamber 201 via the nozzles 249a to 249f, respectively. The N₂ gas supplied from the nozzles 249a to 249f acts as a purge gas, thereby purging the interior of the process chamber 201.

### (Step a2)

After step a1 is completed, a first process gas is supplied to the surface of the wafer 200 in the process chamber 201. The adsorption of the first process gas is inhibited at locations of the surface of the wafer 200 where the first modifying gas was adsorbed in step a1. That is, in step a2, the first process gas containing a first element is supplied to the wafer 200, and the first element is preferentially adsorbed onto a region of the wafer 200 that has not been modified by the first modifying gas.

Specifically, the valve 243a is opened to allow the first process gas to flow into the gas supply pipe 232a. The flow rate of the first process gas is adjusted by the MFC 241a, and the first process gas is supplied into the process chamber 201 via the nozzle 249a and is exhausted through the exhaust port 231a. In this operation, the first process gas is supplied to the wafer 200 (first process gas supplying step). At this time, the valves 243g to 243i and 243n are opened to allow a N₂ gas to be supplied into the process chamber 201 via the nozzles 249b to 249d and 249f, respectively.

(Purging Step sp2)

After nuclei are formed on a lower portion 302 of a recess 300, the valve 243a is closed to stop the supply of the first process gas into the process chamber 201. Then, a gas and the like remaining in the process chamber 201 are removed from the process chamber 201 according to the same process procedures as in the purging step sp1.

[Predetermined Number of Times Performing Step sc1]

By performing a cycle a predetermined number of times (n1 times, where n1 is an integer of 1 or more), the cycle including alternately, i.e., non-simultaneously without synchronization, performing the above-described steps a1 and a2, a film containing the first element can be formed.

In the first film-forming step, it is possible to control the thickness of the film containing the first element formed on the wafer 200 by controlling at least one of the processing temperature and processing time (first modifying gas and first process gas supply time) shown below. In addition, in the first film-forming step, it is also possible to control the thickness of the film containing the first element formed on the wafer 200 by controlling the number of times of performance of the above-mentioned cycle (the number of cycles).

The process conditions in step a1 are exemplified as follows:
First modifying gas supply flow rate: 10 to 1,000 sccm
First modifying gas supply time: 0.5 to 10 minutes
N₂ gas supply flow rate (for each gas supply pipe): 10 to 10,000 sccm
Processing temperature (first temperature): 350 to 420 degrees C.
Processing pressure: 100 to 1,000 Pa

The process conditions in step a2 are exemplified as follows:
First process gas supply flow rate: 10 to 1,000 sccm
First process gas supply time: 0.5 to 10 minutes

Other process conditions are the same as those in step a1.

### (Second Film-Forming Step: S2)

After the first film-forming step S1, a second film-forming step S2 is performed. In the second film-forming step S2, the following steps (processes) are performed.

### (Step b1)

In this step, a second modifying gas is supplied to the wafer 200 in the process chamber 201 to modify at least a portion of the wafer 200.

Specifically, the valve 243d is opened to allow the second modifying gas to flow into the gas supply pipe 232d. The flow rate of the second modifying gas is adjusted by the MFC 241d, and the second modifying gas is supplied into the process chamber 201 via the nozzle 249d and is exhausted through the exhaust port 231a. In this operation, the second modifying gas is supplied to the wafer 200 (second modifying gas supplying step). At this time, the valves 243f, 243g, 243h, 243j, and 243n are opened to allow a N₂ gas to be supplied into the process chamber 201 via the nozzles 249a, 249b, 249c, 249e, and 249f, respectively.

(Purging Step sp3)

Thereafter, the valve 243d is closed to stop the supply of the second modifying gas into the process chamber 201. Then, the interior of the process chamber 201 is vacuum-exhausted to remove a gas and the like remaining in the process chamber 201 from the process chamber 201. At this time, the valves 243f to 243n are opened to allow a N₂ gas to be supplied into the process chamber 201 via the nozzles 249a to 249f, respectively. The N₂ gas supplied from the nozzles 249a to 249f acts as a purge gas, thereby purging the interior of the process chamber 201.

### (Step b2)

After step b1 is completed, a second process gas (second precursor gas) is supplied to the surface of the wafer 200 in the process chamber 201. The adsorption of the second process gas is inhibited at locations of the surface of the wafer 200 where the second modifying gas was adsorbed in step b1. That is, in step b2, the second process gas containing a second element is supplied to the wafer 200, and the second element is preferentially adsorbed onto a region of the wafer 200 that has not been modified by the second modifying gas.

Specifically, the valve 243a is opened to allow the second process gas to flow into the gas supply pipe 232a. The flow rate of the second process gas is adjusted by the MFC 241a, and the second process gas is supplied into the process chamber 201 via the nozzle 249a and is exhausted through the exhaust port 231a. In this operation, the second process gas is supplied to the wafer 200 (second process gas supplying step). At this time, the valves 243g to 243i and 243n are opened to allow a N₂ gas to be supplied into the process chamber 201 via the nozzles 249b to 249d and 249f, respectively.

(Purging Step sp4)

After the film containing the second element are formed on the surface of the wafer 200, the valve 243a is closed to stop the supply of the second process gas into the process chamber 201. Then, a gas and the like remaining in the process chamber 201 are removed from the process chamber 201 according to the same process procedures as in the purging step sp3.

[Predetermined Number of Times Performing Step sc2]

By performing a cycle a predetermined number of times (n2 times, where n2 is an integer of 1 or more), the cycle including alternately, i.e., non-simultaneously without synchronization, performing the above-described steps b1 and b2, a film containing the second element can be formed on the film containing the first element.

In the second film-forming step, it is possible to control the thickness of the film containing the second element formed on the wafer 200 by controlling at least one of the processing temperature and processing time (second modifying gas and second process gas supply time) shown below. In addition, in the second film-forming step, it is also possible to control the thickness of the film containing the second element formed on the wafer 200 by controlling the number of times of performance of the above-mentioned cycle (the number of cycles).

The process conditions in step b1 are exemplified as follows:
Second modifying gas supply flow rate: 10 to 1,000 sccm
Second modifying gas supply time: 0.5 to 10 minutes
N₂ gas supply flow rate (for each gas supply pipe): 10 to 10,000 sccm
Processing temperature (first temperature): 350 to 420 degrees C.
Processing pressure: 100 to 1,000 Pa

The process conditions in step b2 are exemplified as follows:
Second process gas supply flow rate: 10 to 1,000 sccm
Second process gas supply time: 0.5 to 10 minutes

Other process conditions are the same as those in step b1.

### (Temperature Rising Step st1: Temperature Adjusting Step)

After the film containing the second element is formed on the wafer 200, the output of the heater 207 is adjusted so as to change the internal temperature of the process chamber 201, i.e., the temperature of the wafer 200, to a second temperature higher than the above-mentioned first temperature (350 to 420 degrees C.). When performing this step, the valves 243f to 243j and 243n are opened to allow a N₂ gas to be supplied into the process chamber 201 via the nozzles 249a to 249f, and the gas is exhausted through the exhaust port 231a to purge the interior of the process chamber 201. After the temperature of the wafer 200 reaches the second temperature and stabilizes, a step to be described below is started. Here, the second temperature is, for example, in a temperature range of 450 to 550 degrees C.

### (Third Film-Forming Step: S3)

Next, a third film-forming step S3 is performed. In the third film-forming step S3, the following steps (processes) are performed.

### (Step c1)

In this step, a third modifying gas having a decomposition temperature different from the first modifying gas and the second modifying gas is supplied to the wafer 200 in the process chamber 201, i.e., the surface of the film containing the second element formed on the wafer 200, to modify at least a portion of the substrate.

Specifically, the valve 243c is opened to allow the third modifying gas to flow into the gas supply pipe 232c. The flow rate of the third modifying gas is adjusted by the MFC 241c, and the third modifying gas is supplied into the process chamber 201 via the nozzle 249c and is exhausted through the exhaust port 231a. In this operation, the third modifying gas is supplied to the wafer 200 (third modifying gas supplying step). At this time, the valves 243f, 243g, 243i, 243j, and 243n are opened to allow a N₂ gas to be supplied into the process chamber 201 via the nozzles 249a, 249b, 249d, 249e, and 249f, respectively.

(Purging Step sp5)

Thereafter, the valve 243c is closed to stop the supply of the third modifying gas into the process chamber 201. Then, the interior of the process chamber 201 is vacuum-exhausted to remove a gas and the like remaining in the process chamber 201 from the process chamber 201. At this time, the valves 243f to 243j and 243n are opened to allow a N₂ gas to be supplied into the process chamber 201 via the nozzles 249a to 249f, respectively. The N₂ gas supplied from nozzles 249a to 249f acts as a purge gas, thereby purging the interior of the process chamber 201.

### (Step c2)

After step c1 is completed, a third process gas (third precursor gas) is supplied to the surface of the wafer 200 in the process chamber 201. Here, the adsorption of the third process gas is inhibited at locations of the surface of the wafer 200 where the third modifying gas was adsorbed in step c1. That is, in this step, the third process gas containing a third element is supplied to the wafer 200, and the third element is preferentially adsorbed to a region of the wafer 200 that has not been modified by the third modifying gas.

Specifically, the valve 243m is opened to allow the third process gas to flow into the gas supply pipe 232m. The flow rate of the third process gas is adjusted by the MFC 241m, and the third process gas is supplied into the process chamber 201 via the nozzle 249f and is exhausted through the exhaust port 231a. In this operation, the third process gas is supplied to the wafer 200 (third process gas supplying step). At this time, the valves 243g to 243i are opened to allow a N₂ gas to be supplied into the process chamber 201 via the nozzles 249b to 249d, respectively.

(Purging Step sp6)

After the film (third film, third layer) containing the third element is formed on the surface of the wafer 200, the valve 243m is closed to stop the supply of the third process gas into the process chamber 201. Then, a gas and the like remaining in the process chamber 201 are removed from the process chamber 201 according to the same process procedures as in the purging step sp5.

[Predetermined Number of Times Performing Step sc3]

By performing a cycle a predetermined number of times (n3 times, where n3 is an integer of 1 or more), the cycle including alternately, i.e., non-simultaneously without synchronization, performing the above-described steps c1 and c2, a film containing the third element can be formed on the film containing the second element.

The process conditions in the third film-forming step S3 are exemplified as follows:
Third modifying gas supply flow rate: 10 to 5,000 sccm
Third modifying gas supply time: 1 to 300 minutes
Third process gas supply flow rate: 10 to 5,000 sccm
Third process gas supply time: 1 to 300 minutes
N₂ gas supply flow rate (for each gas supply pipe): 10 to 20,000 sccm
Processing temperature (second temperature): 450 to 550 degrees C.
Processing pressure: 30 to 400 Pa

The second substrate processing method obtains the following effects in addition to the effects of the first substrate processing method.

The first film-forming step and the second film-forming step are performed at the same temperature. In addition, the decomposition temperature of the first modifying gas is lower than that of the second modifying gas. This makes it possible to differentiate locations modified by the first modifying gas and the second modifying gas, that is, a region onto which the first element is preferentially adsorbed and a region onto which the second element is preferentially adsorbed, from each other, without changing the temperature in the process chamber 201 between the first film-forming step and the second film-forming step.

In the third film-forming step, the film containing the third element is formed on the film formed with good step coverage by the first film-forming step and the second film-forming step at a temperature higher than those of the first film-forming step and the second film-forming step. Therefore, in the third film-forming step, the film containing the third element can be formed with good step coverage at a higher film-forming rate than in the first film-forming step and the second film-forming step.

In the first film-forming step and the second film-forming step, the decomposition temperature of the first process gas may be the same as that of the second process gas. In addition, the first process gas and the second process gas may be the same gas. From the above, in film formation using process gases with the same decomposition temperature, it is possible to form a film in which the locations onto which the first element (second element) is mainly adsorbed are controlled without changing the temperature conditions. By using this, it is possible to improve the uniformity of the film thickness from the deep portion 302 of the recess 300 to the vicinity 301 of the entrance thereof in the films formed in the first film-forming step and the second film-forming step.

In the second substrate processing method, an example has been described in which a Si film is formed by performing the second film-forming step after the first film-forming step and then performing the third film-forming step. The method of the present disclosure is not limited thereto, and for example, the third film-forming step may be performed after performing a cycle a predetermined number of times, the cycle including the first film-forming step and the second film-forming step.

The present disclosure is not limited to the above-described embodiment, and it goes without saying that various modifications can be made.

In the above-described embodiment, for example, gases including a first halogen element, a second halogen element, and a third halogen element, which are halogen elements, can be used as the first modifying gas, the second modifying gas, and the third modifying gas, respectively. The halogen elements include chlorine (Cl), fluorine (F), bromine (Br), iodine (I), etc. In addition, gases including a first element, a second element, and a third element, and a first halogen element, a second halogen element, and a third halogen element, respectively, may be used as the first modifying gas, the second modifying gas, and the third modifying gas, respectively. Here, the halogen elements have the effect of inhibiting gas adsorption, and is unlikely to remain as impurities in the film, so that it is unlikely to deteriorate the electrical properties of the film.

As the halogen element-containing gas, for example, a halosilane gas containing Si and a halogen element can be used. As the halosilane gas, for example, a chlorosilane gas containing Si and Cl can be used. Examples of the halosilane gas may include a dichlorosilane (SiH₂Cl₂, abbreviation: DCS) gas, a trichlorosilane (SiHCl₃) gas, a tetrachlorosilane (SiCl₄, abbreviation: TCS) gas, a pentachlorodisilane (Si₂H₁Cl₅, abbreviation: PCDS), a hexachlorodisilane (Si₂Cl₆, abbreviation: HCDS) gas, etc. Further, as the halogen element-containing gas, for example, a hydrogen halide gas can be used. Examples of the halogen element-containing gas may include a hydrogen fluoride (HF) gas, a hydrogen chloride (HCl) gas, a hydrogen bromide (HBr) gas, a hydrogen iodide (HI) gas, etc. That is, from among these gases, the first modifying gas, the second modifying gas, and the third modifying gas may be appropriately selected so that the relationship in magnitude between decomposition temperatures is as described in the above-described embodiment.

In the above-described embodiment, when the first element, the second element, and the third element are Si, the first process gas, the second process gas, and the third process gas may be Si-containing gases that contain Si. As the Si-containing gas, for example, a silane gas containing Si as the main element may be used. Examples of the silane gas may include a monosilane (SiH₄, abbreviation: MS) gas, a disilane (Si₂H₆, abbreviation: DS) gas, a trisilane (Si₃H₈, abbreviation: TS) gas, etc. Further, as the silane gas, a halosilane gas may be used.

In the first substrate processing method, the film containing the second element may be formed using the film containing the first element as a seed layer (seed film). This allows high-density crystal nuclei to be formed as the film containing the first element, and the film containing the second element in an amorphous, epitaxial or poly state to be grown using these nuclei as growth nuclei. Similarly, in the second substrate processing method, the film containing the second element may be formed using the film containing the first element as a seed layer. In addition, the film containing the third element may be formed using the film containing the second element as a seed layer. In addition, the film containing the third element may be formed using a film composed of the first element and the second element as a seed layer.

In the above-described embodiment, the first element may be, for example, Si or germanium (Ge), which is a group XIV element, or aluminum (Al), gallium (Ga), or indium (In), which is a group XIII element. In addition, for example, a transition metal element may be used as the first element. Examples of the transition metal element may include titanium (Ti), zirconium (Zr), or hafnium (Hf), which is a group IV element, niobium (Nb) or tantalum (Ta), which is a group V element, molybdenum (Mo) or tungsten (W), which is a group VI element, manganese (Mn), which is a group VII element, ruthenium (Ru), which is a group VIII element, cobalt (Co), which is a group IX element, and nickel (Ni), which is a group X element, as the first element. In addition, as with the first element, these elements may be the second element or the third element.

In the first substrate processing method, the first element and the second element may be different elements. In addition, in the second substrate processing method, one or more of the first element, the second element, and the third element may be different elements.

The decomposition temperature of a high-order halosilane gas is lower than that of a low-order halosilane gas. For example, in the case of halosilane gas, the HCDS gas has a lower decomposition temperature than the TCS gas. That is, when the first modifying gas and the second modifying gas are halosilane gases, the decomposition temperature of the first modifying gas can be made lower than that of the second modifying gas by making the first modifying gas a halosilane gas with a higher order than the second modifying gas. The same relationship also holds when the first modifying gas and the second modifying gas are gases whose main element is an element other than Si. That is, when the first modifying gas and the second modifying gas are gases whose main element is the same element, the decomposition temperature of the first modifying gas can be made lower than that of the second modifying gas by making the first modifying gas a gas with a higher order than the second modifying gas.

The same relationship also holds for the silane gas. For example, the decomposition temperature of the DS gas is lower than that of the MS gas, and the decomposition temperature of the TS gas is lower than that of the DS gas. That is, when the first process gas and the second process gas are silane gases, the decomposition temperature of the first process gas can be made lower than that of the second process gas by making the first process gas a silane gas with a higher order than the second process gas. The same relationship also holds when the first process gas and the second process gas are gases whose main element is an element other than Si. That is, when the first process gas and the second process gas are gases whose main element is the same element, the decomposition temperature of the first process gas can be made lower than that of the second process gas by making the first process gas a gas with a higher order than the second process gas.

In two types of halosilane gases with the same order, the lower the symmetry of the molecules, the lower the decomposition temperature may be. For example, the PCDS gas has a lower decomposition temperature than the HCDS gas, and the TCS gas has a lower decomposition temperature than the DCS gas. That is, in the case where the first modifying gas and the second modifying gas are halosilane gases with the same order, the decomposition temperature of the first modifying gas may be made lower than that of the second modifying gas by making the first modifying gas a halosilane gas with a lower molecular symmetry than the second modifying gas. The same relationship may also hold when the first modifying gas and the second modifying gas are gases with the same order whose main element is an element other than Si. That is, when the first modifying gas and the second modifying gas are gases having the same element as the main element and the same order, the decomposition temperature of the first modifying gas may be made lower than that of the second modifying gas by making the first modifying gas a gas with a lower molecular symmetry than the second modifying gas.

The same relationship may also hold for the first process gas (first precursor gas) and the second process gas (second precursor gas). For example, the DCS gas has a lower decomposition temperature than the MS gas. That is, when the first process gas and the second process gas are silane gases with the same order, the decomposition temperature of the first process gas may be made lower than that of the second process gas by making the molecular symmetry of the first process gas lower than that of the second process gas. The same relationship may also hold when the first process gas and the second process gas are gases having an element other than Si as the main element. That is, when the first process gas and the second process gas are gases having the same element as the main element and having the same order, the decomposition temperature of the first process gas may be made lower than that of the second process gas by making the molecular symmetry of the first process gas lower than that of the second process gas.

In addition, the relationship between the molecular structure and the decomposition temperature in the first modifying gas and the second modifying gas described above also holds when the first modifying gas is replaced with the third modifying gas and when the second modifying gas is replaced with the third modifying gas. In addition, the relationship between the molecular structure and the decomposition temperature in the first process gas (first precursor gas) and the second process gas (first precursor gas) described above also hold when the first process gas (first precursor gas) is replaced with the third process gas (third precursor gas) and when the second process gas (second precursor gas) is replaced with the third process gas (third precursor gas).

In the above-described embodiment (the first substrate processing method or the second substrate processing method), an example has been described in which the cycle of alternately performing step a1 and step a2 is performed a predetermined number of times in the first film-forming step. The method disclosed herein is not limited thereto. For example, in the above-described embodiment, in a cycle after a certain number of times, the supply conditions of the first modifying gas in step a1 or the first process gas (first precursor gas) in step a2 can be changed, or a cycle in which step a1 is not performed can be provided. Similarly, in the above-described embodiment, for example, in a cycle after a certain number of times, the supply conditions of the second modifying gas in step b1 or the second process gas (second precursor gas) in step b2 can be changed, or a cycle in which step b1 is not performed can be provided. Similarly, in the above-described embodiment, in the third film-forming step, for example, in a cycle after a certain number of times, the supply conditions of the third modifying gas in step c1 and the third process gas (third precursor gas) in step c2 can be changed, or a cycle in which step c1 is not performed can be provided.

In the above-described embodiment, an example has been described in which the N₂ gas is used as the inert gas, but this is not limited thereto, and a rare gas such as an argon (Ar) gas, a helium (He) gas, a neon (Ne) gas, a xenon (Xe) gas, etc. may be used as the inert gas.

In the above-described embodiment, an example has been described in which the first precursor gas is supplied as the first process gas into the process chamber 201 (wafer 200) in (a2) of the first film-forming step, but the technique of the present disclosure is not limited thereto. As the first process gas, for example, a silane gas may be supplied as the first precursor gas into the process chamber 201, and as a first reaction gas, for example, an oxygen-containing gas or a nitrogen-containing gas may be supplied into the process chamber 201. Specifically, after supplying the silane gas into the process chamber 201, the valve 243e may be opened to allow the oxygen-containing gas or the nitrogen-containing gas to be supplied as the first reaction gas into the process chamber 201 via the gas supply pipe 232e (first reaction gas supplying step). In that case, a silicon oxide (SiO₂) film or a silicon nitride (SiN) film is formed in the first film-forming step. In addition, at this time, the first precursor gas and the first reaction gas may be sequentially supplied into the process chamber 201 a predetermined number of times.

Similarly, as the second process gas, the second precursor gas and a second reaction gas may be supplied into the process chamber 201, or as the second process gas, the second precursor gas and the second reaction gas may be sequentially supplied into the process chamber 201 a predetermined number of times. Similarly, as the third process gas, the third precursor gas and a third reaction gas may be supplied into the process chamber 201, or as the third process gas, the third precursor gas and the third reaction gas may be sequentially supplied to the process chamber 201 a predetermined number of times. As the second process gas or the third process gas, for example, an oxygen-containing gas or a nitrogen-containing gas may be used.

Examples of the oxygen-containing gas may include an oxygen (O₂) gas, a nitrous oxide (N₂O) gas, a nitric oxide (NO) gas, a nitrogen dioxide (NO₂) gas, an ozone (O₃) gas, water vapor (H₂O gas), a carbon monoxide (CO) gas, a carbon dioxide (CO₂) gas, an O₂ gas+hydrogen (H₂) gas, an O₃ gas+H₂ gas, a H₂O gas+H₂ gas, and the like. Note that in the present disclosure, the description of two gases together such as “O₃ gas+H₂ gas” means a mixture of O₃ gas and H₂ gas. In addition, examples of the nitrogen-containing gas may include nitrogen-containing gases including N—H bonds (N- and H-containing gases) such as an ammonia (NH₃) gas, a hydrazine (N₂H₄) gas, a diazene (N₂H₂) gas, and a N₃H₈ gas, and a N₂ gas.

In the above-described embodiment, an example has been described in which a film is formed using a batch-type substrate processing apparatus that processes a plurality of substrates at a time. The present disclosure is not limited to the above-described embodiment, but can also be suitably applied to a case where a film is formed using a single-wafer substrate processing apparatus that processes a single substrate or several substrates at a time. In addition, in the above-described embodiment, an example has been described in which a film is formed using a substrate processing apparatus provided with a hot-wall-type process furnace. The present disclosure is not limited to the above-described embodiment, but can also be suitably applied to a case where a film is formed using a substrate processing apparatus provided with a cold-wall-type process furnace.

Even in the case of using these substrate processing apparatuses, each process can be performed according to the same process procedures and process conditions as those in the above-described embodiment and modifications, and the same effects as those of the above-described embodiment and modifications can be obtained.

The above-described embodiment and modifications can be used in proper combination. The process procedures and process conditions in this case can be, for example, the same as the process procedures and process conditions of the above-described embodiment and modifications.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a1) modifying at least a portion of the substrate by supplying a first modifying gas to the substrate;
(a2) adsorbing a first element preferentially to a region that is not modified by the first modifying gas, by supplying a first process gas containing the first element to the substrate;
(b1) modifying at least a portion of the substrate by supplying a second modifying gas to the substrate, wherein a decomposition temperature of the second modifying gas is different from a decomposition temperature of the first modifying gas; and
(b2) adsorbing a second element preferentially to a region that is not modified by the second modifying gas, by supplying a second process gas containing the second element to the substrate.

2. The method of claim 1, wherein in (a2), the first process gas includes a first reaction gas and a first precursor gas containing the first element.

3. The method of claim 1, wherein in (b2), the second process gas includes a second reaction gas and a second precursor gas containing the second element.

4. The method of claim 1, wherein a decomposition temperature of the first process gas is the same as a decomposition temperature of the second process gas.

5. The method of claim 1, wherein a temperature at which (a1) and (a2) are performed is the same as a temperature at which (b1) and (b2) are performed.

6. The method of claim 1, further comprising: after performing (a1), (a2), (b1), and (b2) a predetermined number of times,
(c) adsorbing a third element to the substrate by supplying a third process gas containing the third element to the substrate, wherein a decomposition temperature of the third process gas is higher than the decomposition temperature of the first process gas and the decomposition temperature of the second process gas, and
wherein a temperature at which (c) is performed is higher than the temperature at which (a1) and (a2) are performed and the temperature at which (b1) and (b2) are performed.

7. The method of claim 1, wherein (b1) and (b2) are performed a predetermined number of times after (a1) and (a2) are performed a predetermined number of times, and
wherein the decomposition temperature of the first modifying gas is lower than the decomposition temperature of the second modifying gas.

8. The method of claim 7, wherein a temperature at which (a1) and (a2) are performed is lower than a temperature at which (b1) and (b2) are performed.

9. The method of claim 1, wherein a decomposition temperature of the first process gas is lower than a decomposition temperature of the second process gas.

10. The method of claim 1, wherein the substrate includes a recess,
wherein (b1) and (b2) are performed a predetermined number of times after (a1) and (a2) are performed a predetermined number of times,
wherein the decomposition temperature of the first modifying gas is lower than the decomposition temperature of the second modifying gas, and
wherein a region in the recess that the second modifying gas modifies is a deeper side of the recess than a region in the recess that the first modifying gas modifies.

11. The method of claim 10, wherein a temperature at which (a1) and (a2) are performed is lower than a temperature at which (b1) and (b2) are performed.

12. The method of claim 10, wherein a decomposition temperature of the first process gas is lower than a decomposition temperature of the second process gas.

13. The method of claim 1, wherein the first modifying gas contains a first halogen element, and the second modifying gas contains a second halogen element.

14. The method of claim 1, wherein the first modifying gas contains the first element, and the second modifying gas contains the second element.

15. The method of claim 9, wherein a main element of the first modifying gas and a main element of the second modifying gas are a same element, and
wherein the first modifying gas is a gas with a higher order than the second modifying gas.

16. The method of claim 9, wherein a main element of the first modifying gas and a main element of the second modifying gas are a same element,
wherein the first modifying gas and the second modifying gas are gases with a same order, and
wherein a molecular symmetry of the first modifying gas is lower than a molecular symmetry of the second modifying gas.

17. The method of claim 1, wherein in (b2), by using a first layer containing the first element adsorbed onto the substrate in (a2) as a seed layer, a second layer containing the second element is formed.

18. A method of manufacturing a semiconductor device, comprising the method of claim 1.

19. A substrate processing apparatus comprising:
a first modifying gas supply system that supplies a first modifying gas to the substrate;
a first process gas supply system that supplies a first process gas containing a first element to the substrate;
a second modifying gas supply system that supplies a second process modifying gas to the substrate, wherein a decomposition temperature of the second modifying gas is different from a decomposition temperature of the first modifying gas;
a second process gas supply system that supplies a second process gas containing a second element to the substrate in the process chamber; and
a controller configured to be capable of controlling the first modifying gas supply system, the first process gas supply system, the second modifying gas supply system, and the second process gas supply system to perform a process including:
(a1) modifying at least a portion of the substrate by supplying the first modifying gas to the substrate;
(a2) adsorbing the first element preferentially to a region that is not modified by the first modifying gas, by supplying the first process gas to the substrate;
(b1) modifying at least a portion of the substrate by supplying the second modifying gas to the substrate; and
(b2) adsorbing the second element to a region not modified by the second modifying gas, by supplying the second process gas to the substrate and preferentially.

20. A non-transitory computer-readable recording medium storing a program that causes, by a computer, a substrate processing apparatus to perform a process in a process chamber of the substrate processing apparatus, the process comprising:
(a1) modifying at least a portion of a substrate by supplying a first modifying gas to the substrate;
(a2) adsorbing a first element preferentially to a region that is not modified by the first modifying gas, by supplying a first process gas containing the first element to the substrate;
(b1) modifying at least a portion of the substrate by supplying a second modifying gas to the substrate, wherein a decomposition temperature of the second modifying gas is different from a decomposition temperature of the first modifying gas; and
(b2) adsorbing a second element preferentially to a region that is not modified by the second modifying gas, by supplying a second process gas containing the second element to the substrate.
